(19) United States
(12) Patent Application Publication
(10) Pub. No.: US 2017/0145170 A1
(43) Pub. Date: May 25, 2017

(54) Composite Formulation and Composite Product

(71) Applicant: TE Connectivity Corporation, Berwyn, PA (US)

(72) Inventors: Jaydip Das, Cupertino, CA (US); Ting Gao, Palo Alto, CA (US); Mark F. Wartenberg, Redwood City, CA (US); Kavitha Bharadwaj, Fremont, CA (US); Richard B. Lloyd, Sunnyvale, CA (US); Rodney Ivan Martens, Mechanicsburg, PA (US)

(73) Assignee: TE Connectivity Corporation, Berwyn, CA (US)

(21) Appl. No.: 15/425,664

(22) Filed: Feb. 6, 2017

Related U.S. Application Data
(63) Continuation of application No. 14/329,666, filed on Jul. 11, 2014, now abandoned.

(51) Int. Cl. C08J 3/20; H01B 13/00; H05K 9/00; H01R 13/50; B29B 7/90; H01Q 1/36; B29B 7/82; B29C 47/00; B29C 67/24; C08K 3/08; C08K 9/04; C08K 3/36; H01B 1/22; B29B 7/48

(52) U.S. Cl. CPC C08J 3/201; H01B 1/22; H01B 13/0036; H05K 9/0083; H01R 13/50; B29B 7/90; B29B 7/48; B29B 7/82; B29C 47/0004; B29C 67/24; C08K 3/08; C08K 9/04; C08K 3/36; H01Q 1/364; B29K 2105/16

(57) ABSTRACT

A composite formulation and composite product are disclosed. The composite formulation includes a polymer matrix having metal particles, the metal particles including dendritic particles and tin-containing particles. The metal particles are blended within the polymer matrix at a temperature greater than the melt temperature of the polymer matrix. The tin containing particles are at a concentration in the composite formulation of, by volume, between 10% and 36%, and the dendritic particles are at a concentration in the composite formulation of, by volume, between 16% and 40%. The temperature at which the metal particles are blended generates metal-metal diffusion of the metal particles, producing intermetallic phases, the temperature being at least the intermetallic annealing temperature of the metal particles.

### CROSS-REFERENCE TO RELATED APPLICATIONS

This application is continuation of co-pending, commonly assigned U.S. application Ser. No. 14/329,666, filed Jul. 11, 2014, the disclosure of which is incorporated herein by reference.

### FIELD OF THE INVENTION

The present invention is directed to formulations and manufactured products. More particularly, the present invention is directed to composite formulations and composite products having metal or conductive particles.

### BACKGROUND OF THE INVENTION

Electrically conductive metal-plastic composite materials are useful in a variety of components. Lower resistivity or higher conductivity is desirable for improving such components. Extended useful life of such components and easy electrical contact either by soldering or by other industry standard methods (for example, c-clips or pogo pins) to the components are also desirable. Further improvements to such components permit wider use in different environments.

Copper particles can be used in materials to produce relatively good electrically conductive composite formulations. However, such materials are not capable of use in certain applications, are not environmentally-stable when exposed to different extreme conditions required for various electronic, automotive product applications, and are not as conductive as materials including silver. However, silver is expensive and includes operational complexities.

Decreasing the composite resistivity and increasing conductivity of materials, without sacrificing cost, operational complexity, or operational properties continues to be desirable in the art. Also, having low electrical contact resistances and/or stability at extreme environments continues to be desirable in the art.

A composite formulation and composite product that show one or more improvements in comparison to the prior art would be desirable in the art.

### BRIEF DESCRIPTION OF THE INVENTION

In an embodiment, a composite formulation includes a polymer matrix having metal particles, the metal particles including dendritic particles and tin-containing particles. The metal particles are blended within the polymer matrix at a temperature greater than the melt temperature of the polymer matrix. The tin containing particles are at a concentration in the composite formulation of, by volume, between 10% and 36%, and the dendritic particles are at a concentration in the composite formulation of, by volume, between 16% and 40%. The temperature at which the metal particles are blended generates metal-metal diffusion of the metal particles, producing intermetallic phases, the temperature being at least the intermetallic annealing temperature of the metal particles.

In another embodiment, a composite formulation includes a polymer matrix and metal particles, the metal particles including copper particles and tin particles. The metal particles are blended within the polymer matrix at a temperature higher than the melt temperature of the polymer matrix. The temperature at which the metal particles are blended generates metal-metal diffusion of the metal particles, producing one or both of intermetallic phases and alloy phases. The metal particles include morphologies selected from the group consisting of dendrites, spheroid particles, flakes, and blends thereof. The copper particles have a maximum dimension of between 5 micrometers and 50 micrometers. The tin particles have a maximum dimension of between 2 micrometers and 50 micrometers. The tin particles are at a concentration in the composite formulation of, by volume, between 10% and 36%. The copper particles are at a concentration in the composite formulation of, by volume, between 16% and 40%. The composite formulation has a resistivity of less than 0.0006 ohm·cm at 23° C.

In another embodiment, a composite product produced from a composite formulation having metal particles blended within a polymer matrix at a temperature less than an intermetallic annealing temperature includes the polymer matrix and the metal particles, the metal particles, including tin particles and copper particles, and intermetallic compounds formed from at least a portion of the metal particles, the intermetallic compounds being formed by the composite formulation being treated at a temperature of at least the intermetallic annealing temperature during the producing of the composite product.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic view of a composite formulation having a polymer matrix and metal particles, according to an embodiment of the disclosure.

FIG. 2 is a perspective view of shielding that is a composite product formed from a composite formulation, according to an embodiment of the disclosure.

FIG. 3 is a perspective view of an electrical connector that is a composite product formed from a composite formulation, according to an embodiment of the disclosure.

FIG. 4 is a perspective view of an antenna that is a composite product formed from a composite formulation, according to an embodiment of the disclosure.

FIG. 5 shows a scanning electron micrograph of copper dendrites that are constituents of metal particles, according to an embodiment of the disclosure.

FIG. 6 shows a scanning electron micrograph of copper flakes that are constituents of metal particles, according to an embodiment of the disclosure.

FIG. 7 shows a scanning electron micrograph of tin-containing powder that are constituents of metal particles, according to an embodiment of the disclosure.

FIG. 8 shows a cross-section view of a scanning electron micrograph of a composite product, according to an embodiment of the disclosure.

FIG. 9 shows a surface view of a scanning electron micrograph of the composite product of FIG. 8, according to an embodiment of the disclosure.

FIG. 10 shows a surface view of a scanning electron micrograph of a composite product, according to an embodiment of the disclosure.

FIG. 11 shows a surface view of a scanning electron micrograph of the composite product of FIG. 10 after wiping with a contact, according to an embodiment of the disclosure.

FIG. 12 shows a graphical depiction of the x-ray diffraction data for a composite product before and after heat-treatment in controlled atmosphere, according to an embodiment of the disclosure.

FIG. 13 shows a surface view of a scanning electron micrograph of a composite product with resistivity of 0.004 ohm·cm shown in FIG. 15, according to an embodiment of the disclosure.

FIG. 14 shows a surface view of a scanning electron micrograph of a composite product with resistivity of 0.0003 ohm·cm shown in FIG. 15, according to an embodiment of the disclosure.

FIG. 15 shows a graphical depiction of the dependence of the composite product resistivity on one of the example process parameters, such as the screw rotation speed during the composite formulation twin screw extruder mixing at a temperature where the metal-metal diffusion occurs.

FIG. 16 shows a graphical depiction of average contact resistance as a function of load force for the composite product of FIG. 10, according to an embodiment of the disclosure.

FIG. 17 shows a graphical depiction of resistivity as a function of the number of aging days at 85° C. at 85% relative humidity for the composite product of FIG. 10, according to an embodiment of the disclosure.

FIG. 18 shows a graphical depiction of resistivity as a function of the number of aging days at 150° C. in air for the composite product of FIG. 10, according to an embodiment of the disclosure.

FIG. 19 shows a graphical depiction of contact resistance for a composite product under various exposure conditions based upon 200 gm of force, according to an embodiment of the disclosure.

FIG. 20 is a schematic view of a composite product having metal contacts soldered to the composite product, according to an embodiment of the disclosure.

Wherever possible, the same reference numbers will be used throughout the drawings to represent the same parts.

### DETAILED DESCRIPTION OF THE INVENTION

Provided are a composite formulation and a composite product produced from a composite formulation. Embodiments of the present disclosure, for example, in comparison to similar concepts failing to disclose one or more of the features disclosed here, have lower resistivity (higher conductivity), have lower contact force requirements for achieving utilizing such lower resistivity (higher conductivity), have extended operational life (for example, based upon aging data), are capable of being soldered, are capable of being extruded, are capable of being molded, include increased intermetallics and/or alloy phases (such as, based upon similar or different metal particles disclosed herein), include metal-metal diffusion and/or micro-welding (such as, between similar or different metal particles disclosed herein), include increased particle-particle connectivity, and/or are capable of other advantages and distinctions apparent from the present disclosure. As used herein, the term “micro-welding” fusion techniques for small thicknesses (for example, less than 0.5 mm) and small cross-sections (for example, less than 10 mm²), including, but not limited to, welding techniques such as pressure-contact, electric, electrostatic, cold, ultrasonic, thermo-compression, electron-beam, laser, as well as their combinations.

Referring to FIG. 1, a composite formulation 100 includes a polymer matrix 101 and metal particles 103, for example, homogenously blended and/or with the polymer matrix 101 having a concentration, by volume, of between 45% and 70%, between 50% and 55%, between 51% and 54%, between 52% and 54%, between 52% and 53%, 51%, 52%, 52.5%, 53%, 54%, 55%, or any suitable combination, sub-combination, range, or sub-range therein. The blending is by any suitable technique, such as twin-screw blending.

The polymer matrix 101 includes any suitable material capable of having the metal particles 103 blended within it. Suitable materials include, but are not limited to, polyvinylidene fluoride, polyethylene, polyethylene terephthalate, polybutylene terephthalate, liquid crystal polymer, and polymer-copolymer blends with or without process aids. In one embodiment, the polymer matrix 101 permits the composite formulation 100 to be extruded and/or molded (for example, injection molded, thermo-molded, sintered, or a combination thereof).

The composite formulation 100 includes any other suitable constituents. In one embodiment, a process aid is blended within the polymer matrix 101, for example, at a concentration, by volume, of between 3% and 10%, between 6% and 8%, between 7% and 8%, 6%, 7%, 7.5%, 8%, or any suitable combination, sub-combination, range, or sub-range therein. One suitable process aid is a lubricant, such as, dioctyl sebacate silicon-dioxide blend. Other suitable constituents capable of being blended within the polymer matrix 101 include, but are not limited to, a filler (for example, to increase viscosity and/or density), a curing agent (for example, for solvent-based curing and/or for radiation curing), a wetting agent, a defoamer, a dye or coloring agent, or a combination thereof.

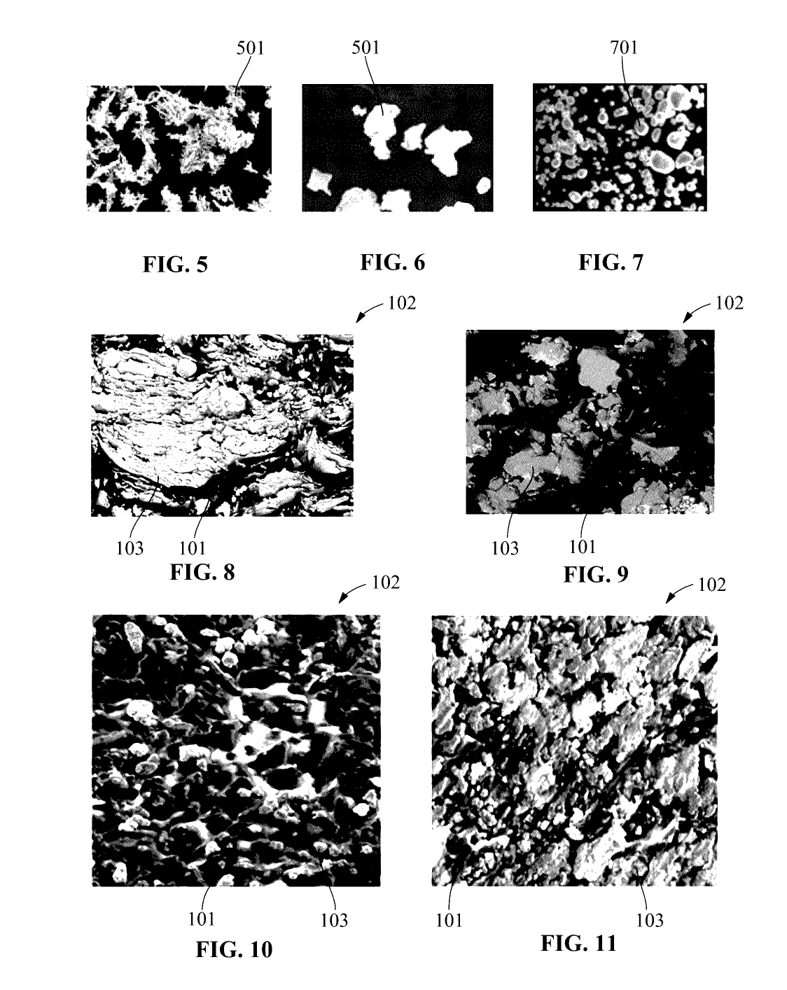

The metal particles 103 in the composite formulation 100 include dendritic particles 501 (see FIGS. 5-6) and tin-containing particles 701 (see FIG. 7), such as tin or tin alloys. The metal particles 103 are blended within the polymer matrix 101 at a temperature above the polymer melt temperature and at which metal-metal diffusion occurs to give rise to intermetallic or alloy phases or compositions, such as, the intermetallic formation temperature. In one embodiment, the blending is at a temperature lower than the melting temperature of the tin-containing particles 701, such as, 232° C. for tin, or the melting temperature of the tin alloy. Suitable temperature ranges for the blending include, but are not limited to, less than 230° C., less than 220° C., less than 210° C., between 180° C. and 230° C., between 180° C. and 220° C., between 180° C. and 210° C., between 190° C. and 200° C., between 195° C. and 205° C., or any suitable combination, sub-combination, range, or sub-range therein.

In one embodiment, the molding or extrusion temperature is above the melt temperature of the polymer 101 and above or below the melt temperature of the tin-containing particles 701 to further complete the intermetallic diffusion and phase formation. Suitable temperature ranges for the molding or the extrusion include, but are not limited to, less than 300° C., less than 270° C., less than 250° C., less than 210° C., less than 180° C., between 210° C. and 170° C., between 180° C. and 220° C., between 190° C. and 230° C., between 200° C. and 240° C., between 230° C. and 270° C., between 260° C. and 300° C., or any suitable combination, sub-combination, range, or sub-range therein.

The metal particles 103 include two or more types of metals. The metal particles 103 are any suitable dimensions and morphologies capable of being blended within the polymer matrix 101. Suitable values for the maximum dimension of the metal particles 103 include, but are not limited to, 100 micrometers, 80 micrometers, 50 micrometers, 30 micrometers, 10 micrometers, 5 micrometers, 2 micrometers, less than 100 micrometers, less than 80 micrometers, between 50 micrometers and 100 micrometers, between 50 micrometers and 80 micrometers, between 30 micrometers and 100 micrometers, between 30 micrometers and 80 micrometers, between 30 micrometers and 50 micrometers, or any suitable combination, sub-combination, range, or sub-range therein.

The dendritic particles 501 and the tin-containing particles 701 are similar in size or different in size. Suitable maximum dimensions for the dendritic particles 501 include, but are not limited to, between 25 micrometers and 50 micrometers, between 25 micrometers and 50 micrometers, between 15 micrometers and 25 micrometers, or any suitable combination, sub-combination, range, or sub-range therein. Suitable maximum dimensions for the tin-containing particles 701 include, but are not limited to, between 2 micrometers and 50 micrometers, between 10 micrometers and 30 micrometers, between 5 micrometers and 25 micrometers, or any suitable combination, sub-combination, range, or sub-range therein.

Suitable morphologies for the metal particles 103 include, but are not limited to, dendrites, spheroid particles, flakes, powder, or a combination of morphologies. In one embodiment, the dendritic particles 501 and the tin-containing particles 701 differ in morphologies. In one embodiment, the tin-containing particles 701 include a morphology of spherical or cylindrical powder and/or the dendrites 501, for example, having copper particles, as shown in FIG. 5, flakes 601 as shown in FIG. 6, spheroid particles, or a blend of such morphologies. In one embodiment, the metal particles 103 include two morphologies (thereby being binary as is shown in FIGS. 8-9), three morphologies (thereby being ternary), or four morphologies (thereby being quaternary).

The concentration of the metal particles 103, such as, the dendritic particles 501 and the tin-containing particles 701, provides desired properties for the composite formulation 100. The metal particles 103 are at a concentration in the composite formulation 100 of, by volume, between 30% and 50%, between 35% and 45%, between 38% and 42%, between 39% and 41%, 38%, 39%, 40%, 41%, 42%, or any suitable combination, sub-combination, range, or sub-range therein.

In one embodiment, the dendritic particles 501 and/or the copper are at a concentration in the composite formulation 100 of, by volume, between 16% and 40%, between 16% and 20%, between 20% and 24%, between 10% and 30%, between 18% and 22%, 10%, 16%, 18%, 20%, 22%, 24%, 30%, or any suitable combination, sub-combination, range, or sub-range therein.

In one embodiment, the tin-containing particles 701 are at a concentration in the composite formulation 100 of, by volume, between 10% and 36%, between 16% and 30%, between 25% and 36%, between 10% and 40%, between 20% and 30%, between 24% and 28%, 10%, 16%, 20%, 24%, 25%, 28%, 30%, 36%, 40%, or any suitable combination, sub-combination, range, or sub-range therein.

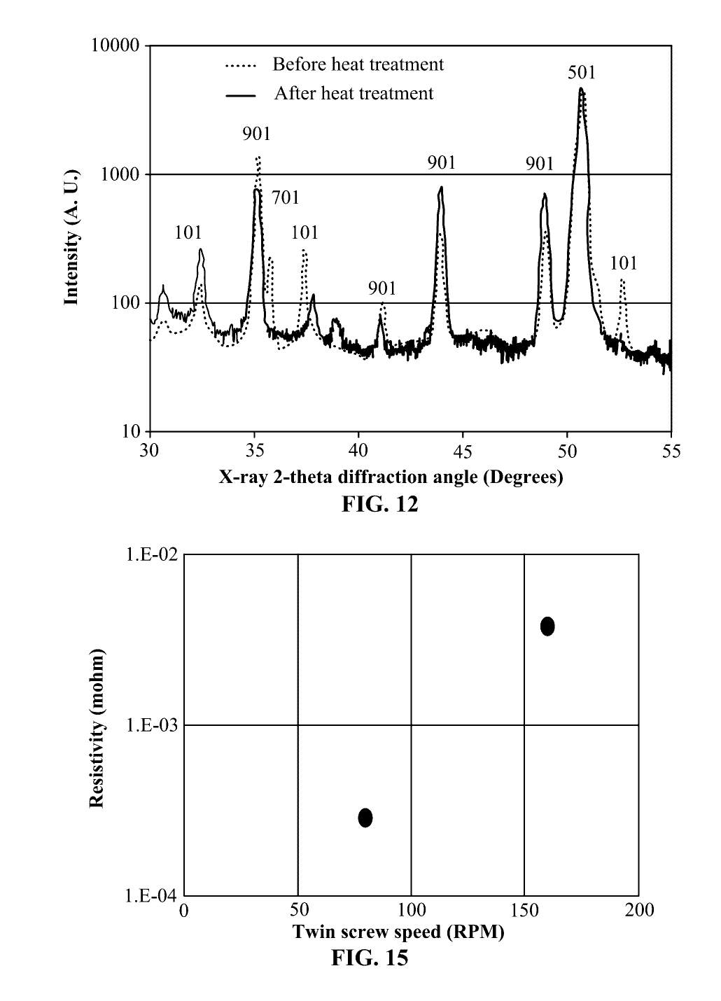

In one embodiment, a molded or extruded composite product 102 made of the composite formulation 100 has intermetallic or alloy phases or compositions 901 at the metal particle interfaces (see FIG. 12) in addition to the polymer matrix 101 and the dendritic particles 501 and/or the tin-containing particles 701.

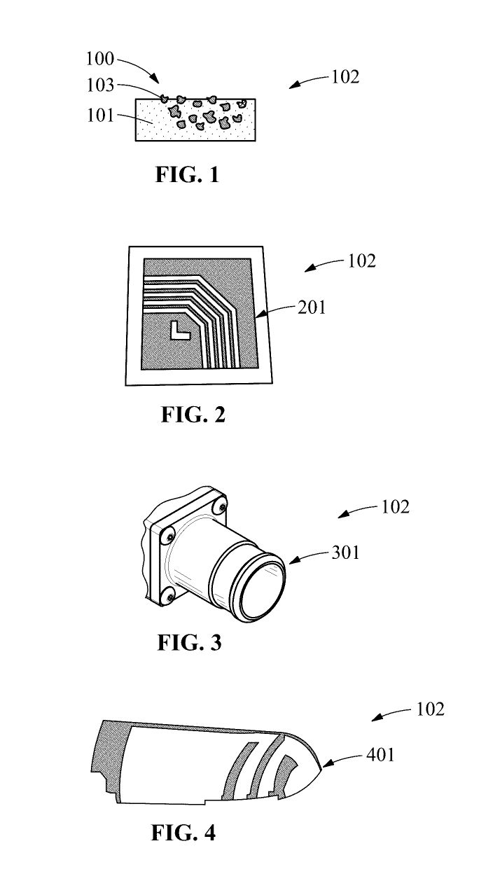

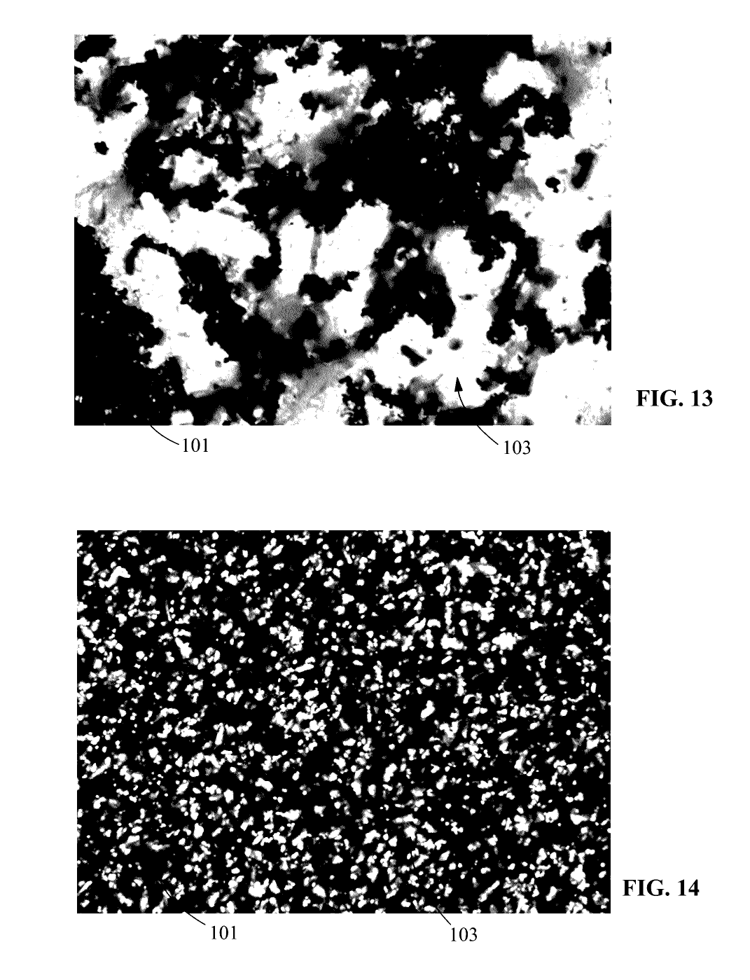

The mixing or molding or extrusion process parameters affect the particle distribution, mixing, intermetallic or alloy phase formation of the composite formulation (See FIG. 13 and FIG. 14). For example, such parameters are capable of including, but are not limited to, screw design, screw rotation speed of a twin screw extruder, and temperatures at different regions of the extruder. The particle-particle connectivity as well as the bulk resistivity depends upon these process parameters. The composite formulation 100 provides a level of bulk resistivity (and corresponding conductivity) that permits lower electrical resistances for certain process parameters (see FIG. 15 showing a lower resistivity value corresponding with FIG. 14 and a higher resistivity value corresponding with FIG. 13). For example, in one embodiment, the composite formulation 100 has a resistivity of less than 0.0006 ohm·cm, less than 0.0004 ohm·cm, less than 0.00035 ohm·cm, between 0.00015 and 0.00030 ohm·cm, or any suitable combination, sub-combination, range, or sub-range therein. Based upon such a resistivity (and corresponding conductivity), the composite formulation 100 is capable of being used in a composite product 102, such as, shielding 201 (see FIG. 2), a connector housing 301 (see FIG. 3), or an antenna 401 (see FIG. 4).

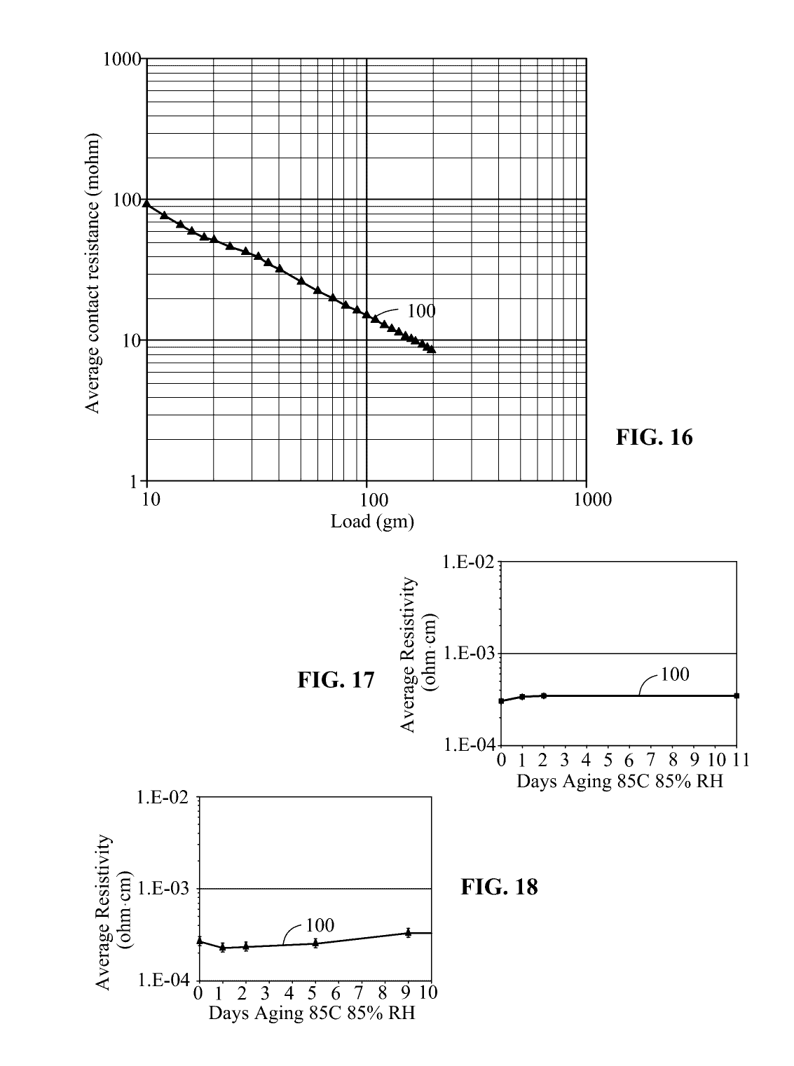

The composite formulation 100 permits electrical connection at a level of force that is less than that which is necessary for electrically connecting with a comparative formulation (not shown) having copper but not tin or a tin alloy, for example, with the comparative formulation having resistivity of between 0.0005 to 0.001 ohm·cm. As shown in FIG. 16, in one embodiment, the composite formulation 100 provides a suitable electrical contact resistance, as measured per ASTM B539-02, standard test for measuring resistance of electrical connections. Suitable electrical contact resistance values include, but are not limited to, less than 100 milliohms at force between 10 gm and 50 gm from a 6 mm gold-coated ball, less than 50 milliohms at force between 50 gm and 100 gm from a 6 mm gold-coated ball, less than 50 milliohms at force between 50 gm and 100 gm from a 6 mm gold-coated ball, less than 50 milliohms at force between 100 gm and 200 gm from a 6 mm gold-coated ball, less than 20 milliohms at force between 100 gm and 200 gm from a 6 mm gold-coated ball, or any suitable combination, sub-combination, range, or sub-range therein. Similarly, in one embodiment, the composite formulation achieves less variation in resistance values at a force of 400 gm, in comparison to the comparative formulation.

The composite formulation 100 is capable of maintaining electrical resistivity and hence, the percolated network connection at temperatures of 85° C. or 150° C. for a longer duration than the comparative formulation (not shown) having copper but not tin or tin alloys, for example, with the comparative formulation having resistivity of between 0.0005 to 0.001 ohm·cm. For example, although the comparative formulation increase from 0.0005 ohm·cm to 0.005 ohm·cm over a period of 100 hours at 150° C. air, in one embodiment, the composite formulation 100 maintains resistivity (and corresponding conductivity) of less than 0.0006 ohm·cm over 12 days in 85° C. air less than 0.0006 ohm·cm over 10 days in 85° C. and 85% relative humidity, as shown in FIG. 17, and/or less than 0.0006 ohm·cm over 10 days in 150° C. air, as shown in FIG. 18. In a further embodiment, the composite formulation 100 maintains resistivity (and corresponding conductivity) of less than 0.0006 ohm·cm over 1 day in 248° C. to 258° C. air.

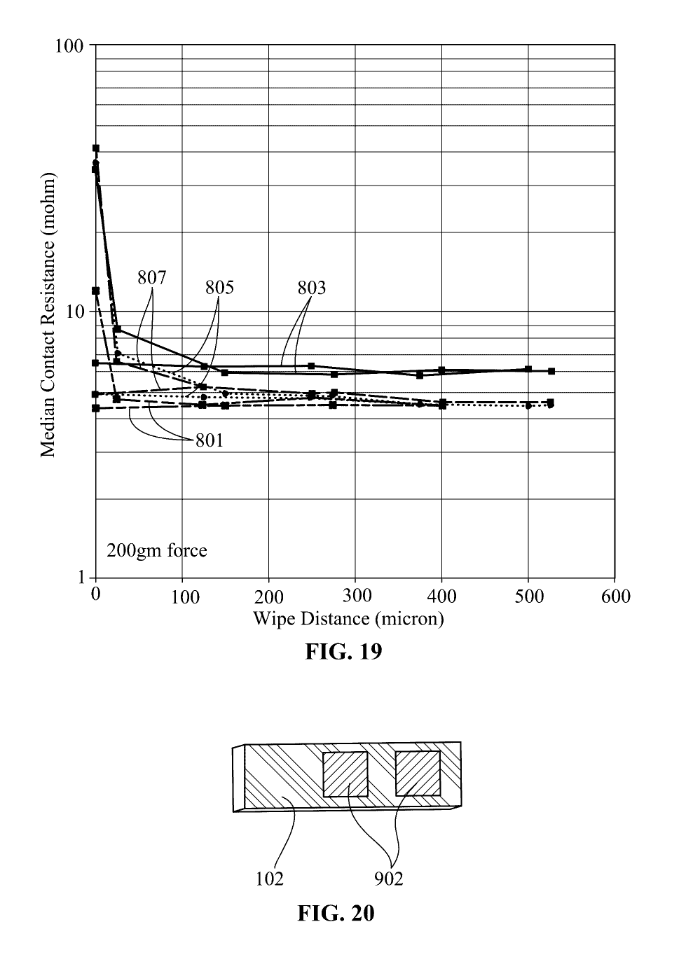

The composite product 102 is capable of maintaining electrical contact resistance when exposed to various exposure conditions. FIG. 19 shows the contact resistance for an embodiment of the composite product 102 under various exposure conditions based upon 200 gm of force. For example, under a first set of conditions 801 that include exposing the composite product 102 to temperatures of 85° C. or 150° C. in air for 10 days, the electrical contact resistance is between 4 and 5 milliohm, after a wiping of at least 25 micrometers. Under a second set of conditions 803 that include exposing the composite product 102 to a temperature of 85° C. and 85% relative humidity for 10 days, the electrical contact resistance is between 5 and 7 milliohm, after a wiping of at least 100 micrometers. Under a third set of conditions 805 that include exposing the composite product 102 to temperature cycles from 25° C. to 65° C. at 95% relative humidity for 10 days, the electrical contact resistance is between 4 and 5 milliohm, after a wiping of at least 150 micrometers. Under a fourth set of conditions 807 that include exposing the composite product 102 to mixed flowing gas (for example, MFG class IIa) for 2 days at conditions which metallic copper generally corrodes and shows degradation in the contact resistance responses, the electrical contact resistance is between 4 and 5 milliohm, after a wiping of at least 300 micrometers. As used herein, the term “degradation” refers to a loss of greater than 30% of an initial electrical resistivity and/or initial contact resistance. Under all four sets of the conditions, about a 25 um wipe maintains the contact resistance below 10 milliohm at a force of 200 gm even after exposure to high temperatures, or temperature-humidity cycles, or mixing flowing gas.

In one embodiment, the composite product 102 is post-treated below or above the melt temperature of the tin-containing particles 701 in a controlled vacuum or gas atmosphere. The treating is during the production of the composite product 102 from the composite formulation 100, for example, during extruding and/or during molding or is after the producing of the composite product 102. In one embodiment, the treating is in a controlled atmosphere, for example, being inert, substantially consisting of argon and/or nitrogen, any other suitable inert atmosphere, or being in a vacuum. In one embodiment, the treating permits the composite formulation 100 to further form and/or stabilize intermetallic or alloy compounds (see FIG. 12). In one embodiment, the treating permits the composite formulation 100 to have increased particle-particle connectivity, offering partial or full coverage of the intermetallic or alloy phases on the metal particles 103. Suitable temperature ranges for the treating include, but are not limited to, above or below 230° C., between 180° C. and 250° C., between 220° C. and 250° C., between 240° C. and 250° C., or any suitable combination, sub-combination, range, or sub-range therein. Suitable durations of the treating include, but are not limited to, at least 5 minutes, at least 30 minutes, at least 1 hour, at least 3 hours, at least 6 hours, between 5 minutes and 30 minutes, between 15 minutes and 1 hour, between 30 minutes and 1 hour, between 15 minutes and 6 hours, between 1 hour and 4 hours, between 1 hour and 3 hours, between 2 hours and 6 hours, or any suitable combination, sub-combination, range, or sub-range thereof.

In comparison to the composite product 102 when produced without the treating, the treating decreases resistivity (and increases corresponding conductivity), for example, by a factor of 2 to 10 times. Additionally or alternatively, in one embodiment, the treating decreases contact force requirements, for example, to a force of 25 to 50 gm, such as 30 gm, being capable of maintaining a contact resistance of less than 0.1 ohm. In one embodiment, the operational life of the composite product 102 is extended in comparison to the composite product 102 when produced without the treating.

Referring to FIG. 10, in one embodiment, the composite formulation 100 and/or the composite product 102 includes at least a portion of the metal particles 103 extending through the surface of the polymer matrix 101. In a further embodiment, the composite formulation 100 and/or the composite product 102 are wiped or smeared (for example, with a contact), as is illustrated by FIG. 11, thereby increasing the proportion of the surface area of the composite formulation and/or composite product 102 that includes the metal particles 103.

In one embodiment, the composite formulation 100 or the composite product 102 is reflowed or hand-soldered, for example, at least 6 times while maintaining resistivity within 30% of an initial electrical resistivity. Referring to FIG. 20, in one embodiment, the reflow or the hand-soldering uses solder that is lead-free or lead-based to produce metal contacts 902 on the composite product 102.

### EXAMPLES

In a first example, according to an embodiment of the disclosure, the composite product is exposed to various wiping distances under 200 gm of force at temperatures of 85° C. or 150° C. in air for 10 days. The resulting electrical contact resistance is shown by the first set of conditions 801 in FIG. 19.

In a second example, according to an embodiment of the disclosure, the composite product is exposed to various wiping distances under 200 gm of force at temperatures of 85° C. and 85% relative humidity for 10 days. The resulting electrical contact resistance is shown by the second set of conditions 803 in FIG. 19.

In a third example, according to an embodiment of the disclosure, the composite product is exposed to various wiping distances under 200 gm of force and temperature cycles from 25° C. to 65° C. at 95% relative humidity for 10 days. The resulting electrical contact resistance is shown by the third set of conditions 805 in FIG. 19.

In a fourth example, according to an embodiment of the disclosure, the composite product is exposed to various wiping distances under 200 gm of force and mixed flowing gas (for example, MFG class IIa) for 2 days at conditions which metallic copper generally corrodes. The resulting electrical contact resistance is shown by the fourth set of conditions 807 in FIG. 19.

In a fifth example, according to an embodiment of the disclosure, the composite formulation includes, by volume, polyvinylidene fluoride (PVDF) at 52.5%, dioctyl sebacate silicon-dioxide at 7.5%, copper dendrite at 24%, and tin powder at 16%. Prior to heat treatment, the bulk resistivity is 5×10⁻⁴ ohm·cm and the contact resistance at 100 gm force is 350 milliohm. After heat treatment, the bulk resistivity is 2×10⁻⁴ ohm·cm and the contact resistance at 100 gm force is 15-40 milliohm.

In a sixth example, according to an embodiment of the disclosure, the composite formulation includes, by volume, polyvinylidene fluoride (PVDF) at 52.5%, dioctyl sebacate silicon-dioxide at 7.5%, copper dendrite at 16%, and tin powder at 24%. Prior to heat treatment, the bulk resistivity is 3×10⁻⁴ ohm·cm and the contact resistance at 100 gm force is 15-40 milliohm.

While the invention has been described with reference to one or more embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A method of making a composite formulation, said method comprising:
providing a polymer matrix having a melt temperature;
providing metal particles, said metal particles comprising dendritic particles at a concentration of between 10% and 36% by volume and tin-containing particles;
blending the polymer matrix and the metal particles at a temperature greater than the melt temperature of the polymer matrix;
generating metal-metal diffusion of the metal particles during the blending to produce intermetallic phases, the temperature of blending being at least the intermetallic annealing temperature of the metal particles; and
producing the composite formulation wherein the dendritic particles are at a concentration in the composite formulation of between 16% and 40% by volume and the tin containing particles are at a concentration of between 10% and 36% by volume.

2. The method of claim 1, further comprising adding a process aid to the polymer matrix.

3. The method of claim 1, further comprising extruding the composite formulation.

4. The method of claim 3, further comprising forming a composite product by the extruding, said composite product having electrical contact resistance of less than 100 milliohm at forces of 30 gm per ASTM standard B539-02.

5. The method of claim 1, further comprising molding the composite formulation.

6. The method of claim 5, further comprising forming a composite product by the molding, said composite product having electrical contact resistance of less than 100 milliohm at forces of 30 gm per ASTM standard B539-02.

7. The method of claim 1, wherein the blending is done below the melt temperature of the tin containing particles.

8. The method of claim 1, wherein the blending is between 180° C. and 230° C.

9. The method of claim 1, further comprising forming the composite formulation into a composite product.

10. The method of claim 9, the composite product being an electrical component selected from the group consisting of an antenna, shielding, and a connector housing.

11. The method of claim 9, the composite product being solderable with one or both of lead-based solder and lead-free solder.

12. The method of claim 9, further comprising exposing the composite product to 150° C. for 10 days, wherein the composite product maintains electrical resistivity and contact resistance within 30% of an initial electrical resistivity and an initial contact resistance prior to such exposure.

13. The method of claim 1, wherein the blending is conducted with a twin-screw extruder.

14. The method of claim 1, further comprising extruding or molding the composite formulation at a temperature less than 300° C.

15. The method of claim 1, further comprising
forming a composite product from the composite formulation; and
treating the composite product in a controlled vacuum or gas atmosphere.

16. The method of claim 15, wherein treating is conducted at a temperature where the metal-metal diffusion occurs.

17. The method of claim 1, wherein the dendritic particles have a maximum dimension of between 5 micrometers and 100 micrometers.

18. The method of claim 1, wherein the tin-containing particles have a maximum dimension of between 2 micrometers and 50 micrometers.

19. The method of claim 1, wherein the polymer matrix includes a polymer selected from the group consisting of polyvinylidene fluoride, polyethylene, polyethylene terephthalate, polybutylene terephthalate, and liquid crystal polymer.

20. The method of claim 1, wherein the composite formulation has an electrical resistivity of less than 0.0006 ohm·cm at 23° C.
